(19) United States
(12) Patent Application Publication
(10) Pub. No.: US 2007/0257290 A1
(43) Pub. Date: Nov. 8, 2007

(54) MEMORY STRUCTURE AND MEMORY DEVICE

(75) Inventors: Ming-Tzong Yang, Hsinchu (TW); Wan-Chun Liao, Hsinchu County (TW); Sheng-Chin Lee, Hsinchu City (TW); Hsiao-Lin Chen, Hsinchu County (TW); Chien-Hao Lee, Taipei City (TW); Shr-Wei Shiu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 11/778,100

(22) Filed: Jul. 16, 2007

Related U.S. Application Data
(62) Division of application No. 11/306,901, filed on Jan. 16, 2006.

(51) Int. Cl. H01L 29/94

(52) U.S. Cl. 257/296; 257/E27.084

(57) ABSTRACT

A memory structure, a memory device and a manufacturing method thereof are provided. First, a substrate is provided and a dielectric layer is formed over the substrate. Then, a pattern is formed in the dielectric layer. An amorphous silicon layer is formed in the pattern and over the dielectric layer. The amorphous silicon layer is patterned to form an electrode over the pattern. Then, a spacer is formed on the sidewall of the electrode. A selective hemispherical grains (HSGS) layer is formed over the surface of the electrode and the surface of the spacer.

### CROSS-REFERENCE TO RELATED APPLICATION

This application is a divisional of an application Ser. No. 11/306,901, filed Jan. 16, 2006, now pending. The entirety of the above-mentioned patent application is hereby incorporated by reference herein and made a part of this specification.

### BACKGROUND OF THE INVENTION

1. Field of the Invention

The present invention relates to a semiconductor device and a manufacturing method thereof, and more particularly to a high capacitance memory device and a manufacturing method thereof.

2. Description of the Related Art

As the integration of semiconductor technology advances, the size of semiconductor structures must be shrink to increase the density of devices in the integrated circuits. The shrinkage of the structure, however, will raise corresponding problems. FIG. 1 is a schematic drawing showing a conventional dynamic random access memory (DRAM). Referring to FIG. 1, the DRAM 100 comprises a plurality of memory units 102, bit lines BL1, BL2 to BLm, and word lines WL1, WL2 to WLn. Each of the memory units 102 is composed of a transistor 112 and a capacitor 114. Generally, each capacitor 114 of the corresponding memory units 102 is selectively charged or discharged through the transistor 112 to store data. For example, if charges are stored in the capacitor 114, the logic state of the memory unit 102 is “1”; when no charge is stored in the capacitor 114, the logic state of the memory unit 102 is “0.” One of ordinary skill in the art knows that charges stored in the capacitor 114 of the DRAM 100 should reach a level so that the DRAM 100 can be correctly read or written.

For the memory designed with the Ultra Large Scale Integrated (ULSI) circuit, when dimensions of devices shrink, capacitances of the DRAM also decline. As a result, when charges stored in the capacitor 114 of the DRAM 100 are decreased, data stored in the capacitor 114 cannot be correctly read. In addition, the charge loss of the capacitor 114 is unavoidable due to the leakage current issue. Accordingly, periodic refreshes to the capacitor 114 are required to maintain charges stored in the capacitor above a minimum measurable level so that the data stored in the capacitor 114 can be correctly accessed. As a result, the smaller the capacitance of the capacitor 114, the more times of refreshing the capacitor 114 are required. However, during the refresh step, the DRAM 100 cannot perform read or write operations. Accordingly, with industrial development, to increase the capacitance of each unit area of the capacitor of the memory becomes important when the semiconductor technology moves forward to the deep sub-micron era.

### SUMMARY OF THE INVENTION

Accordingly, the present invention is directed to a method for manufacturing a memory structure. The method effectively increases the capacitances of the capacitor so that the accuracy of accessing data can be improved. In addition, the frequency of refreshing the memory structure is also reduced.

The present invention is also directed to a memory structure. The memory structure has high capacitances so that the accuracy of accessing data can be improved. In addition, the frequency of refreshing the memory structure is also reduced.

The present invention is also directed to a memory device. The memory device has high capacitances so that the accuracy of accessing data can be improved. Moreover, the frequency to refresh the memory device is also reduced.

The present invention provides a method for manufacturing a memory structure. First, a substrate is provided, wherein a dielectric layer is formed over the substrate. Then, a patter is formed in the dielectric layer. Next, an amorphous silicon layer is formed within the pattern and over the dielectric layer. Then, the amorphous silicon layer is then patterned, wherein at least a portion of the amorphous silicon layer over the pattern forms an electrode. Next, a spacer is formed on a sidewall of the electrode. Thereafter, a selective hemispherical grains (SHGS) layer is formed over a surface of the electrode and a surface of the spacer.

According to one embodiment of the present invention, the pattern comprises a trench, a via or a plug.

According to one embodiment of the present invention, a material of the spacer comprises amorphous silicon. In addition, a thickness of the spacer is in a range of about 10 nm to about 100 nm. It is preferred that the thickness of the spacer is in a range of about 10 nm to about 60 nm.

According to one embodiment of the present invention, the memory comprises a dynamic random access memory (DRAM).

According to one embodiment of the present invention, the material of the SHSG layer comprises silane (SiH₄), or disilane (Si₂H₆).

According to one embodiment of the present invention, the material of the SHSG layer comprises a mixture of silane and helium.

According to one embodiment of the present invention, the SHSG layer is formed over the surface of the electrode and the surface of the spacer by a grain-growth method under a vacuum environment. Additionally, a thermal treatment may be performed to the SHSG layer.

According to one embodiment of the present invention, a transistor has been formed over the substrate.

The present invention also provides a memory structure. The memory structure comprises a substrate, a dielectric layer, an amorphous silicon layer, a spacer, and a SHSG layer. Wherein, the dielectric layer is over the substrate, and has a pattern therein. The amorphous layer at least is formed within and over the pattern to form an electrode. The spacer is on a sidewall of the electrode. The SHSG layer is over a surface of the electrode and a surface of the spacer.

The present invention also provides a memory device. The memory device comprises a plurality memory cells, a plurality of bit lines and a plurality word lines. Wherein, the memory cells are arranged in an array, and each of the memory cells comprises: a gate, a source/drain region, an amorphous layer, a spacer and a SHSG layer. The gate is over a substrate. The source/drain region is within the substrate and adjacent to the gate. The amorphous silicon layer is over a portion of the substrate adjacent to the source/drain region to form an electrode. The spacer is on a sidewall of the electrode. The SHSG layer is over a surface of the electrode and a surface of the spacer. The bit lines are over the substrate, and are coupled to the source region of each of the memory cells. The word lines are coupled to the gate of each of the memory cells.

The present invention forms the spacer on the sidewall of the electrode to increase the area of the electrode, and forms the SHSG layer over the surface of the spacer and the surface of the electrode. Accordingly, the surface area of the capacitor is increased. Due to the increase of the surface area of the capacitor by the method or structure described above, the present invention solves the problem in the prior art. The present invention also reduces the frequency to refresh the memory so that the manufacturing yield is enhanced.

One or part or all of these and other features and advantages of the present invention will become readily apparent to those skilled in this art from the following description wherein there is shown and described one embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

FIG. 1 is a schematic drawing showing a conventional dynamic random access memory (DRAM).

FIGS. 2A-2E are schematic cross sectional views showing a method for manufacturing a memory structure according to an embodiment of the present invention.

FIGS. 3A-3F are schematic cross sectional views showing a method for manufacturing a memory according to an embodiment of the present invention.

FIG. 4 is a schematic cross sectional view of a memory structure according to another embodiment of the present invention.

FIG. 5A is a schematic cross sectional view showing a circuit of a memory device according to an embodiment of the present invention.

FIG. 5B is a schematic cross sectional view of a memory structure according to an embodiment of the present invention.

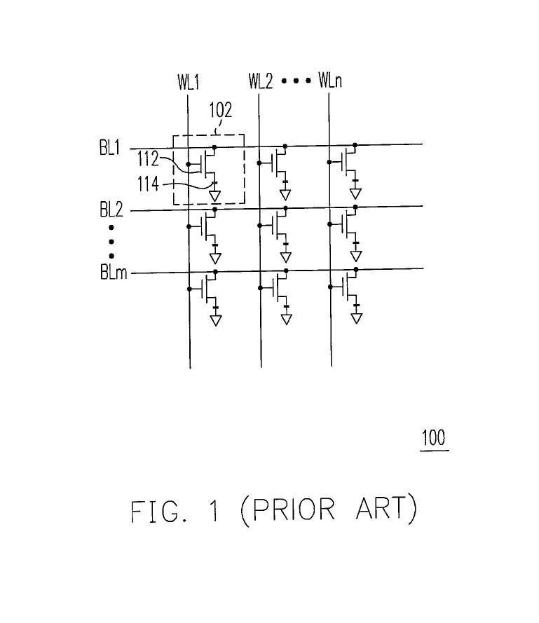

### DESCRIPTION OF EMBODIMENTS

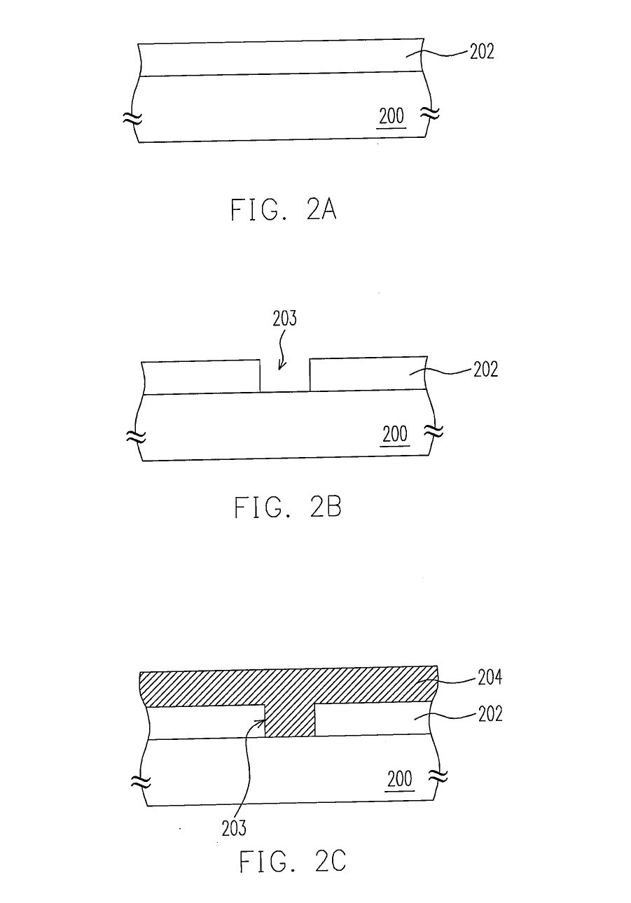

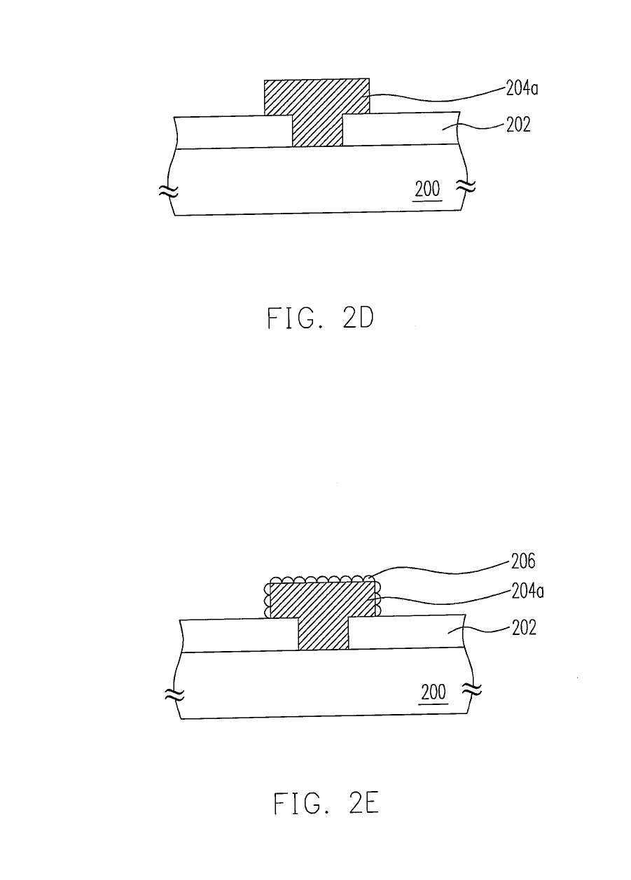

The present invention provides the memory with high capacitances due to the requirement of industrial development and process advance. Following are descriptions of the method for manufacturing the memory structure and memory device. FIGS. 2A-2E are schematic cross-sectional views showing a method for manufacturing a memory structure according to an embodiment of the present invention.

Referring to FIG. 2A, a dielectric layer 202 is formed over the substrate 200. A transistor (not shown) is formed over the substrate 200. Wherein, the material of the dielectric layer 202 can be, for example, silicon oxide, silicon nitride or silicon oxynitride. The method of forming the dielectric layer 202 can be a chemical vapor deposition (CVD) process, for example.

Referring to FIG. 2B, a contact window opening 203 is formed within the dielectric layer 202, wherein the method of forming the contact window opening 203 can comprise, for example, a photolithographic process and an etch process. An amorphous silicon layer 204 is then filled in the contact window opening 203 and over the dielectric layer 202 as shown in FIG. 2C.

Referring to FIG. 2D, a patterning process is performed to the amorphous silicon layer 204 to define the capacitor area and form the electrode, i.e., the amorphous silicon layer 204a of the capacitor. A selective hemispherical grains (SHGS) layer 206 is formed over the surface of the electrode, i.e., the amorphous silicon layer 204a, as shown in FIG. 2E. As a result, the surface area of the capacitor is thus increased.

According to the manufacturing method described above, a cross-sectional view of a memory device of an embodiment of the present invention is shown in FIG. 2E. Referring to FIG. 2E, the memory comprises the substrate 200, the dielectric layer 202, the electrode 204a, and the SHSG layer 206. Wherein, a transistor (not shown) is formed over the substrate. The dielectric layer 202 is over the substrate 200, and has an opening therein. In addition, the electrode 204a is within the opening of the dielectric layer 202 and covers a portion of the dielectric layer 202. The SHSG layer 206 is over the surface of the electrode 204a.

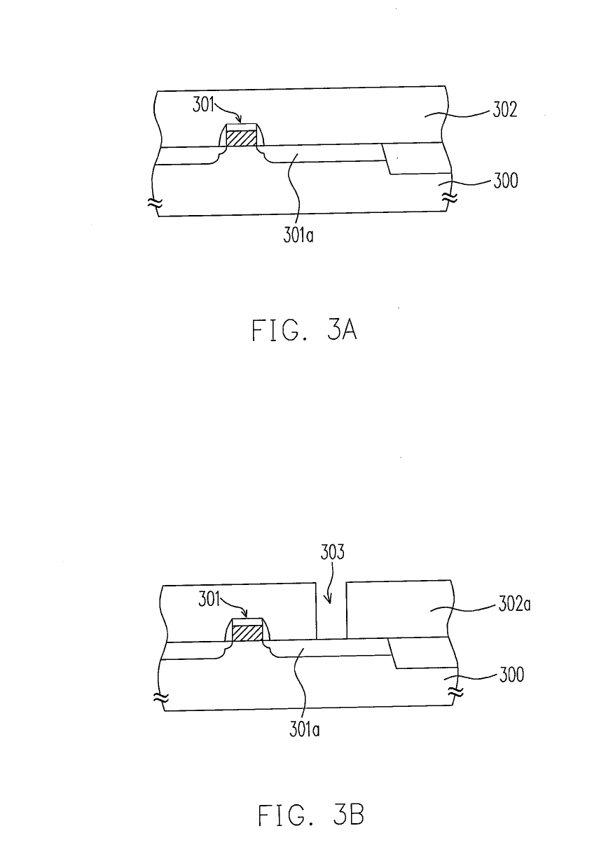

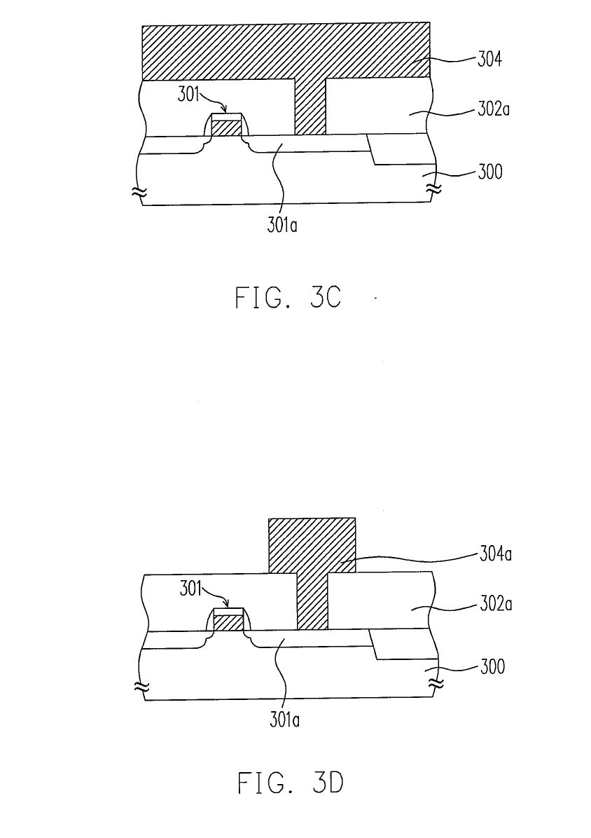

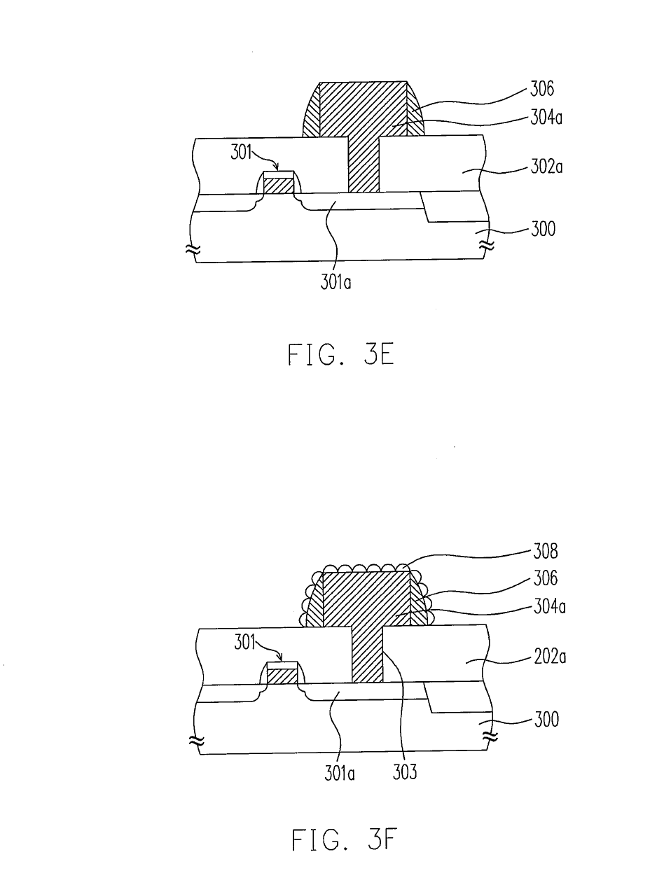

In another embodiment of the present invention, the dimension of the capacitor of the memory device is increased to effectively increase the capacitance of the memory. FIGS. 3A-3F are schematic cross sectional views showing a method for manufacturing a memory according to an embodiment of the present invention.

Referring to FIG. 3A, a substrate 300 is provided. A dielectric layer 302 is formed over the substrate 300. In one embodiment of the present invention, the material of the dielectric layer 302 can be, for example, silicon oxide, silicon nitride, or silicon oxynitride. The method of forming the dielectric layer 302 can be a CVD process, for example. In addition, the transistor 301 is formed over the substrate 300, and the transistor 301 comprises a gate and source/drain region 301a.

Referring to FIG. 3B, a pattern 303 is formed within the dielectric layer 302. The pattern 303 exposes a portion of the source/drain region 301a of the transistor 301, and the dielectric layer 302 becomes a patterned dielectric layer 302a. In one embodiment of the present invention, the method of forming the pattern 303 within the dielectric layer 302 comprises a photolithographic process and an etch process, for example. The pattern 303 can be, for example, a trench, a via or a plug.

Referring to FIG. 3C, an amorphous silicon layer 304 is then formed over the substrate 300 and filled in the pattern 303 to electrically couple to the source/drain region 301a. In one embodiment of the present invention, the material of the amorphous silicon layer 304 can be, for example, doped amorphous silicon, and the dopant can be arsenic or phosphorous, for example, to enhance the conductivity of the amorphous silicon layer 304. In one embodiment of the present invention, the method for forming the amorphous silicon layer 304 can be a low pressure chemical vapor deposition (LPCVD) process, for example.

Referring to FIG. 3D, a patterning process is performed to the amorphous silicon layer 304, wherein a portion of the amorphous silicon layer 304 over the pattern 303 is reserved to form an electrode, i.e., the amorphous silicon layer 304a. The method of patterning the amorphous silicon layer 304 comprises, for example, a photolithographic process and an etch process, to remove the other portion of the amorphous silicon layer 304 and expose the portion of the dielectric layer 302a.

Referring to FIG. 3E, a spacer 306 is formed on the sidewall of the electrode, i.e., the amorphous silicon layer 304a. Wherein, the material of the spacer 306 can be, for example, amorphous silicon. In addition, the thickness of the spacer 306 is in a range of about 10 nm to about 100 nm. It is preferred that the thickness of the spacer 306 is in a range of about 10 nm to about 60 nm. Note that the spacer 306 and the electrode, i.e., the amorphous silicon layer 304a, may be serve as the capacitor area of the memory device of the present invention. Accordingly, the capacitance of the memory of the present invention is thus increased.

Referring to FIG. 3F, a SHSG layer 308 is formed over the surface of the electrode, i.e., the amorphous silicon layer 304a, and the surface of the spacer 306. Wherein, the SHSG layer 308 can be formed from silane (SiH₄) or disilane (Si₂H₆), for example. In addition, the SHSG layer 308 can also be formed from a mixture of silane and helium. The SHSG layer 308 can be formed by, for example, performing a grain-growth method to form the SHSG layer 308 over the surface of the electrode 304a and the surface of the spacer 306 under vacuum environment. A thermal treatment is then performed to the SHSG layer 308.

Accordingly, the surface area of the capacitor can be increased by forming the SHSG layer 308 over the surface of the electrode, i.e., the amorphous silicon layer 304a, and the surface of the spacer 306. As a result, the capacitance of the memory is thus increased.

In the embodiment shown in FIGS. 3A-3F, the memory device can be a dynamic random access memory (DRAM), for example. The present invention, however, is not limited thereto. The present invention can be applied to other memory devices.

Hereinafter, the memory structure formed by the method for manufacturing the memory device described above will be discussed.

Referring to FIG. 3F, the memory structure may comprise the substrate 300, the dielectric layer 302a, the amorphous silicon layer 304a, spacer 306, and the SHSG layer 308. Wherein, the dielectric layer 302a is over the substrate 300, and the dielectric layer 302 has a pattern 303. The amorphous silicon layer 304a is at least within and over the pattern 303 to form an electrode. In addition, the spacer 306 is on the sidewall of the electrode, i.e., the amorphous silicon layer 304a. The SHSG layer 308 is over the surface of the electrode, i.e., the amorphous silicon layer 304a, and the surface of the spacer 306. Therefore, the surface area of the capacitor is increased, and the capacitance of the memory is also increased.

In one embodiment of the present invention, the material of the spacer 306 can be amorphous silicon, for example. The thickness of the spacer 306 can be, for example, in a range of about 10 nm to about 100 nm. It is preferred that the thickness of the spacer is in a range of about 10 nm to about 60 nm, for example. The pattern 303 can be, for example, a trench, a via or a plug. In addition, the SHSG layer 308 can be formed from, for example, silane or disilane. In addition, the SHSG layer 308 may also be formed from a mixture of silane and helium. Wherein, the memory structure can be, for example, a DRAM.

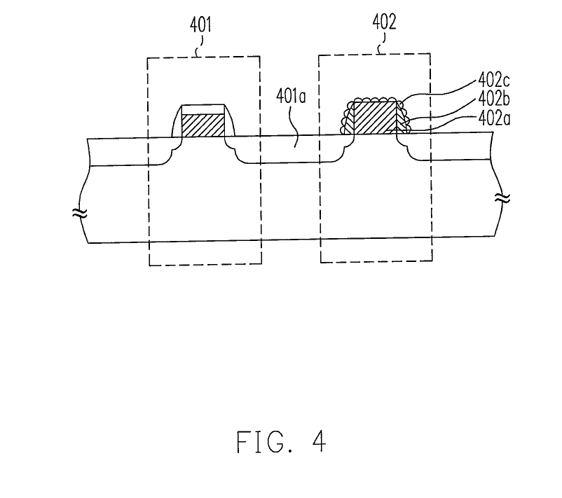

In another embodiment, the method for manufacturing the memory device according to the present invention can also generate the memory structure as shown in FIG. 4. The memory structure of FIG. 4 comprises the transistor 401 and the capacitor 402. The capacitor 402 connects with the transistor 401 through the source/drain region 401a. Wherein, the capacitor 402 comprises the amorphous silicon layer 402a, the spacer 402b and the SHSG layer 402c. The SHSG layer 402c is over the surface of the amorphous silicon layer 402a and the surface of the spacer 402b. The surface area of the capacitor 402 is increased and the capacitance of the memory is also increased. The present invention, however, is not limited to the memory devices shown in FIGS. 3F and 4 and may be adopted for any memory structure for increasing the capacitance of the capacitor.

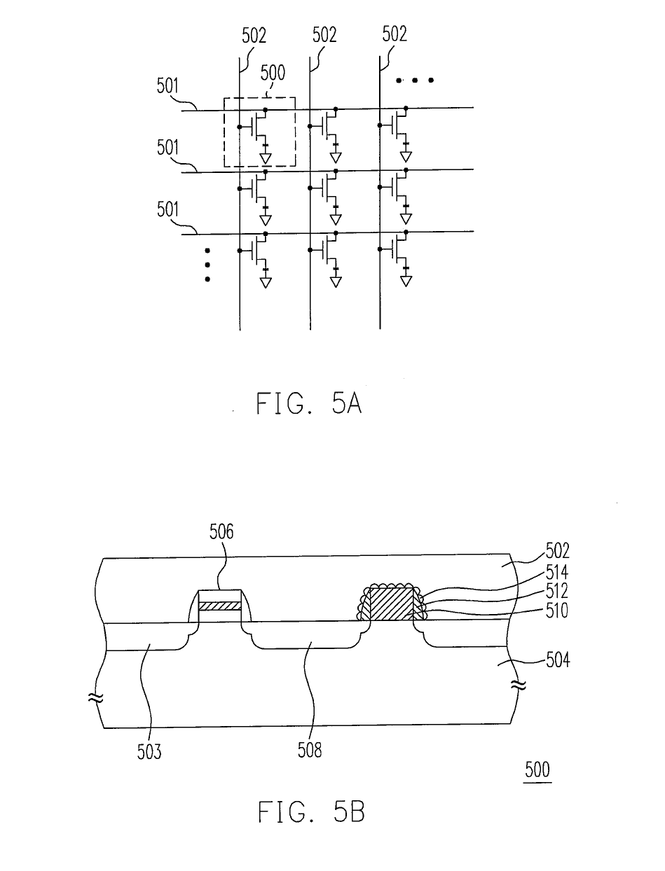

In another embodiment, the method of manufacturing the memory according to the present invention may also form the memory device in the circuit shown in FIG. 5A. The memory device of FIG. 5A comprises a plurality of memory cells, a plurality bit lines 501 and a plurality word lines 502. The memory cells are arranged in array, wherein each of these memory cells 500 is coupled to a bit line 501 and a word line 502. In one embodiment of the present invention, each of the bit lines 501 is orthogonal to each of the word lines 502. FIG. 5B is a schematic cross sectional view of a memory cell of FIG. 5A. The memory cell 500 comprises a gate 506, a source 503, a drain region 508, an amorphous silicon layer 510, a spacer 512, and a SHSG layer 514. Wherein, the gate 506 is over the substrate 504, and the source region 503 and the drain region 508 are within the substrate 504 being adjacent to the gate 506. The amorphous silicon layer 510 is over the substrate 504 that adjacent to the drain region 508 to form an electrode. The spacer 512 is on the sidewall of the electrode, i.e., the amorphous silicon layer 510. The SHSG layer 514 is over the surface of the electrode, i.e., the amorphous silicon layer 510, and the surface of the spacer 512. In addition, the bit line 501 is coupled to the source region 503 of each of the memory cells 500, and the word line 502 are over the substrate 504 and coupled to the gate 506 of each of the memory cells 500.

Wherein, the material of the spacer 512 can be amorphous silicon, for example. The thickness of the spacer 512 can be, for example, in a range of about 10 nm to about 100 nm. It is preferred that the thickness of the spacer is in a range of about 10 nm to about 60 nm, for example. In addition, the SHSG layer 308 can be formed from, for example, silane or disilane. In addition, the SHSG layer 308 may also be formed from a mixture of silane and helium. In this embodiment, the SHSG layer 514 increases the surface areas of the amorphous silicon layer 510 and the spacer 512. Therefore, the surface area of the capacitor is increased, and the capacitance of the memory is also increased.

Accordingly, in the present invention, spacers are formed on the sidewall of the electrode of the capacitor of the memory. Therefore, the area fo the electrode of the capacitor of the memory is increased, and the capacitance of the memory is thus enhanced. Additionally, in the present invention, a SHSG layer is formed over the spacer and the surface of the electrode of the capacitor of the memory to increase the surface area of the capacitor. Therefore, the capacitance of the memory is also increased. The problem confronted in the prior art technology can be thus overcome. Moreover, by increasing the capacitance of the memory, the times to refresh the memory are reduced, and the manufacturing yield is also improved.

The foregoing description of the embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A memory structure, comprising:
a substrate;
a dielectric layer over the substrate, wherein the dielectric layer comprising a pattern;
an amorphous layer at least formed within and over the pattern to form an electrode;
a spacer on a sidewall of the electrode; and
a selective hemispherical grains (SHSG) layer over a surface of the electrode and a surface of the spacer.

2. The memory structure of claim 1, wherein the pattern comprises a trench, a via or a plug.

3. The memory structure of claim 1, wherein a material of the spacer comprises amorphous silicon.

4. The memory structure of claim 1, wherein a thickness of the spacer is in a range of about 10 nm to about 100 nm.

5. The memory structure of claim 1, wherein a thickness of the spacer is in a range of about 10 nm to about 60 nm.

6. The memory structure of claim 1, wherein the memory comprises a dynamic random access memory (DRAM).

7. The memory structure of claim 1, wherein a material of the SHSG layer comprises silane (SiH₄), or disilane (Si₂H₆).

8. The memory structure of claim 1, wherein a material of the SHSG layer comprises a mixture of silane and helium.

9. A memory device, comprising:
a plurality of memory cells arranged in an array, wherein each of the memory cells comprises:
a gate over a substrate;
a source/drain region within the substrate and adjacent to the gate;
an amorphous silicon layer over a portion of the substrate adjacent to the source/drain region to form an electrode;
a spacer on a sidewalls of the electrode; and
a selective hemispherical grains (SHSG) layer over a surface of the electrode and a surface of the spacer;
a plurality of bit lines over the substrate, the bit lines are coupled to the source region of each of the memory cells; and
a plurality of word lines, the word lines are coupled to the gate of each of the memory cells.

10. The memory device of claim 9, wherein a material of the spacer comprises amorphous silicon.

11. The memory device of claim 9, wherein a thickness of the spacer is in a range of about 10 nm to about 100 nm.

12. The memory device of claim 9, wherein a thickness of the spacer is in a range of about 10 nm to about 60 nm.

13. The memory device of claim 9, wherein a material of the SHSG layer comprises silane (SiH₄), or disilane (Si₂H₆).

14. The memory device of claim 9, wherein a material of the SHSG layer comprises a mixture of silane and helium.
